(19) United States
(12) Patent Application Publication
(10) Pub. No.: US 2004/0145002 A1
(43) Pub. Date: Jul. 29, 2004

(54) Method of fabricating a ferroelectric capacitor and a ferroelectric capacitor produced by the method

(76) Inventors: Chin-Lin Liu, Hsinchu (TW); T.B. Wu, Hsinchu (TW); Sheng Chih Lai, Hsinchu (TW)

Correspondence Address: Kenton R. Mullins, Stout, Uxa, Buyan & Mullins, LLP, Suite 300, 4 Venture, Irvine, CA, 92618, US

(21) Appl. No.: 10/714,531

(22) Filed: Nov. 13, 2003

Related U.S. Application Data
(60) Provisional application No. 60/426,061, filed on Nov. 13, 2002.

(51) Int. Cl. H01L 21/00; H01L 29/76

(52) U.S. Cl. 257/295; 438/3

(57) ABSTRACT

A method is described for fabricating a ferroelectric capacitor that overlies a metal-oxide-semiconductor transistor. Low temperature processes are employed to deposit a conducting layer and a ferroelectric layer on an insulating layer that separates the transistor from the ferroelectric capacitor.

### CROSS-REFERENCE TO RELATED APPLICATIONS

This application claims the benefit of U.S. Provisional Application No. 60/426,061, filed Nov. 13, 2002 and entitled LOW TEMPERATURE MOCVD LNO/PZT/LNO CAPACITORS FOR HIGH DENSITY EMBEDDED FERAM, the entire contents of which are hereby incorporated by reference.

### BACKGROUND OF THE INVENTION

1. Field of the Invention

The present invention relates generally to semiconductor fabrication methods and, more particularly, to fabrication of a ferroelectric capacitor.

2. Description of Related Art

Memory is a critical component of any computing device. Memory can take a variety of forms according to the function that the memory serves in the computing device. Nearly any computing device comprises some amount of volatile memory or random-access-memory (RAM) that is used by the computing device to perform its functions. Non-volatile memory forms another important component of the vast majority of computing devices in use today. For example, embedded computers in commercial products such as microwave ovens, toasters, clock radios, and the like normally employ read-only-memory (ROM). ROM is compact in size, is programmed only once, and is low in cost. Therefore, ROM is a good choice of a memory medium for storing instruction sequences that control button-pushing, beeping, timing, and the like. Other types of non-volatile memory, including programmable read-only memory (PROM), electrically erasable programmable read-only memory (EEPROM), and flash memory are in common use today in a wide variety of applications. These types of memory generally are fabricated of semiconductor material.

Historically, memory elements in large computers were formed of ferromagnetic materials until approximately the 1960's. A ferromagnetic element, for example a small doughnut-shaped toroid, is capable of storing one bit of information in the form of the direction of magnetic flux imparted to the element by means of an applied electric current. Ferromagnetic memory stores information in response to current passed through an elemental inductor, the core of which is formed of ferromagnetic material. When the source of current is removed, the ferromagnetic material retains a magnetic state according to the direction of the current. This magnetic state can have one of two values and therefore is capable of storing one bit of information. The property of material being able to retain a magnetic state after an external stimulus has been removed is one example of a phenomenon known as hysteresis. The hysteresis property of ferromagnetic material makes it able to act as a memory storage element.

As the size of computers decreased, magnetic memory was supplanted with various forms of semiconductor memory. Ferromagnetic memories are not in common use today.

While ferromagnetic memory no longer finds practical use in the majority of computer applications, ferroelectric memory is a subject of current interest. Ferroelectric memory stores information in an elemental capacitor. Generally, a capacitor is formed of two conducting parallel plates separated by a dielectric (i.e. insulating material). One form of ferroelectric memory comprises a ferroelectric capacitor in which the dielectric is formed of ferroelectric material. While ferromagnetic memory stores information in an elemental inductor in response to applied current, ferroelectric memory stores information in a ferroelectric capacitor in response to voltage applied between the plates of the capacitor. When the source of applied voltage is removed, a hysteresis effect in the ferroelectric material of the capacitor stores an electric state in the material. This hysteresis effect can be exploited in order to use the ferroelectric capacitor as a memory element.

Ferroelectric capacitors possess properties that make their use as memory elements attractive. Among these properties are high speed, low power consumption, low operating voltage, and high endurance. Ferroelectric capacitors, however, have proven to be difficult to fabricate in forms that make them truly useful in practice. However, integrating a ferroelectric capacitor with conventional CMOS processes can raise relatively difficult fabrication issues. Ferroelectric thin films must be annealed at a temperature of at least 650° C. in order to achieve the proper crystal phase (e.g., a perovskite phase) for ferroelectricity. Employing such high temperature processes can lead to problems of oxidation of CMOS interconnects associated with the ferroelectric capacitors. One alternative for solving the high temperature problem has been to employ a low temperature process for forming platinum electrodes for the ferroelectric capacitor. This approach may not be workable in contexts where platinum electrodes exhibit problems of reliability. Generally, the prior-art has required fabrication of a ferroelectric capacitor before it is connected to a transistor in order to circumvent problems created by the high temperature processes involved. This approach, however, may be undesirable for embedded applications.

A need thus exists in the prior art for a relatively low temperature method of fabricating ferroelectric capacitors. A further need exists for a method of fabricating ferroelectric capacitors with electrodes that have fewer reliability issues.

### SUMMARY OF THE INVENTION

The present invention addresses these needs by providing, in accordance with one aspect, low temperature processes for fabricating ferroelectric capacitors over metal-oxide-semiconductor transistors. In accordance with another aspect of the present invention described herein, methods of fabricating ferroelectric capacitors having electrodes formed of conducting oxides substantially free of reliability issues are provided.

According to one implementation of a method of the present invention, a metal-oxide-semiconductor transistor may be fabricated on a substrate, and an insulating layer can be deposited on the metal-oxide-semiconductor transistor. A conducting layer is deposited on the insulating layer using a low temperature process, and a ferroelectric layer may be deposited on the conducting layer using a low temperature process.

According to another implementation of the present invention, a manufacturing method of fabricating a ferroelectric capacitor in an integrated circuit comprises fabricating a metal-oxide-semiconductor transistor on a substrate, depositing an insulating layer on the metal-oxide-semiconductor, depositing a conducting layer on the insulating layer using a process to cause at least part of the conducting layer to form a perovskite phase, and depositing a ferroelectric layer on the conducting layer using a process to cause at least part of the ferroelectric layer to form a perovskite phase.

Another embodiment of the present invention comprises a semiconductor element produced according to an implementation as described above, wherein the depositing of the conducting layer on the insulating layer comprises depositing a first conducting layer on the insulating layer and depositing a second conducting layer on the first conducting layer.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112.

Any feature or combination of features described herein are included within the scope of the present invention provided that the features included in any such combination are not mutually inconsistent as will be apparent from the context, this specification, and the knowledge of one skilled in the art. For purposes of summarizing the present invention, certain aspects, advantages and novel features of the present invention are described herein. Of course, it is to be understood that not necessarily all such aspects, advantages or features will be embodied in any particular embodiment of the present invention. Additional advantages and aspects of the present invention are apparent in the following detailed description and claims that follow.

### BRIEF DESCIRPTION OF THE FIGURES

FIG. 1 is a flow diagram depicting a representative implementation of a method for fabricating a ferroelectric capacitor according to the present invention;

FIG. 2 is a flow diagram describing a representative implementation of a method for fabricating a ferroelectric capacitor according to another aspect of the present invention; and

FIGS. 3-5 are cross-sectional views of successive stages of implementations of the methods of FIGS. 1 and 2 of the present invention.

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed to cover all modifications, alternatives, and equivalents of the embodiments as may fall within the spirit and scope of the invention as defined by the appended claims. It is to be understood and appreciated that the process steps and structures described herein do not cover a complete process flow for the manufacture of ferroelectric capacitors. The present invention may be practiced in conjunction with various integrated circuit fabrication techniques that are conventionally used in the art, and only so much of the commonly practiced process steps are included herein as are necessary to provide an understanding of the present invention. The present invention has applicability in the field of semiconductor devices and processes in general. For illustrative purposes, however, the following description pertains to a method of fabricating a ferroelectric capacitors that overlies a metal-oxide-semiconductor (MOS) transistor disposed on a semiconductor substrate.

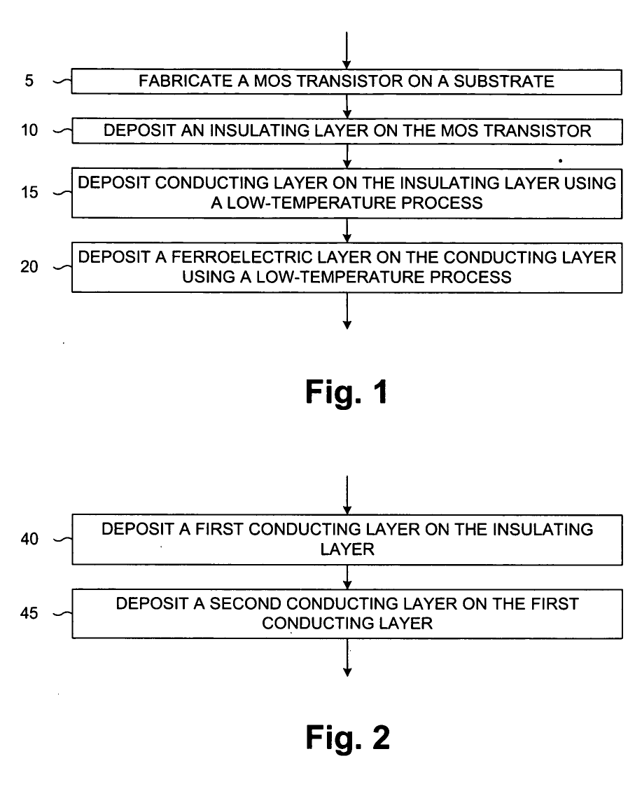

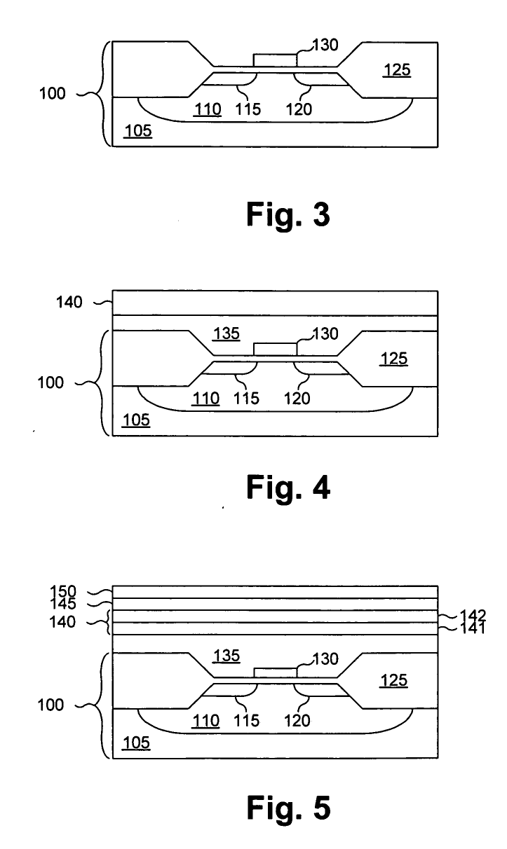

Referring more particularly to the drawings, FIG. 1 is a flow diagram that depicts one representative implementation of a method for fabricating a ferroelectric capacitor according to the present invention. The description of this implementation refers to FIGS. 3-5. With reference to FIGS. 1 and 3, a metal-oxide-semiconductor (MOS) transistor 100 is fabricated on a substrate at step 5. Techniques for fabricating a MOS transistor are well known in the art. Generally, a MOS transistor 100 is formed on a substrate 105 that may be, for example, a semiconductor wafer (e.g., a silicon wafer). A region 110 of the substrate 105 may be doped to increase the electrical conductivity of the substrate. According to one exemplary embodiment, the region 110 is diffused or implanted with dopant atoms (e.g., antimony). A source region 115 and a drain region 120 typically are formed in the doped region 110, and an oxide layer 125 is formed above the source 115 and drain 120 regions. The oxide layer 125 may be formed substantially of, for example, silicon dioxide. A gate 130, typically formed substantially of doped polysilicon, is formed above the oxide layer 125. In some embodiments, provision is made to provide electrical contact with the source 115, the drain 120, and the gate 130. These contacts are not shown in FIGS. 3-5.

With reference to FIGS. 1 and 4, an oxide layer 135 is deposited on the MOS transistor 100 at step 10, and a conducting layer 140 is deposited on the oxide layer 135 at step 15 using a low temperature process. The oxide layer 135, which may be formed substantially of silicon dioxide, and which may be grown or deposited to a thickness of about 600˜800 nm, provides electrical isolation between the MOS transistor 100 and the conducting layer 140. The conducting layer 140 may be formed using a number of low-temperature processes, such as sputtering, to thereby form one electrode of a ferroelectric capacitor. In an exemplary embodiment, the conducting layer 140 is formed to a thickness of about 40˜200 nm using a sputtering low-temperature process. In some embodiments, a via (not shown) may be provided to connect the conducting layer 140 with, for example, the source 115 of the MOS transistor 100.

FIG. 2 is a flow diagram that describes an alternative implementation of step 15 of FIG. 1 for forming a conducting layer over an insulating layer. With reference to FIGS. 2 and 5, a first conducting layer 141 is deposited at step 40. A second conducting layer 142 is deposited at step 45. The first conducting layer 141 may be formed on the oxide layer 135 at step 40, and the second conducting layer 142 can be formed on the first conducting layer 141 at step 45. The first conducting layer 141 may be formed, for example, of platinum and may be applied using a low temperature process, such as sputtering, to a thickness of about 20˜100 nm. According to one embodiment of the ferroelectric capacitor, the first conducting layer 141 is formed of iridium that may be applied to a thickness of about 50˜80 nm using a low temperature process, such as sputtering.

The second conducting layer 142, according to an exemplary embodiment of the ferroelectric capacitor, is formed of a conducting oxide layer. As an illustrative example, the conducting oxide layer may be formed substantially of lanthanum nickle oxide (LaNiO₃) referred to as LNO, using a low-temperature process such as sputtering, to a thickness within a range of about 20 nm to about 100 nm. According to another example, the conducting oxide may be formed substantially of iridium oxide (IrO₂), using a sputtering low-temperature process, to a thickness within a range of about 20 nm to about 100 nm. According to a preferred implementation of the present method, an LNO second conducting layer 142 is formed by sputtering at a temperature of about 350° C. to thereby form a second conducting layer 142 having a thickness of about 20˜100 nm. In accordance with an aspect of the present invention, this low-temperature process can cause the LNO to form a perovskite phase. Overlaying the first conducting layer 141 with the LNO second conducting layer 142 can substantially to attenuate or eliminate reliability issues, such as fatigue and retention, which may otherwise be associated with the use of a single first conducting layer 141 formed, for example, of platinum.

With reference to FIGS. 1 and 5, a layer of ferroelectric material 145 is then deposited on the conducting layer 140 using a low temperature process at step 20. According to an exemplary embodiment, the layer of ferroelectric material 145 is deposited on the second conducting layer 142. The ferroelectric material layer 145 may be formed of lead zirconate titanate (PZT) and may be deposited to a thickness of about 50˜200 nm by metal organic chemical vapor deposition (MOCVD) at a temperature substantially in a range of about 450° C. to about 550° C. This process can cause the PZT to form a perovskite phase, thus enabling the material to exhibit a ferroelectric effect. In accordance with one aspect of the present invention, formation of the perovskite phase can be enhanced by the presence of an LNO second conducting layer 142 that likewise forms a perovskite phase as described supra. It will be appreciated that the low temperatures employed in the step of depositing the LNO and the PZT can make it possible to fabricate a ferroelectric capacitor over an underlying MOS transistor 100 with an attenuation of or elimination of damage to the MOS transistor 100 in the process.

According to a typical example, fabrication of the ferroelectric capacitor can be completed by depositing a conducting layer 150 on the ferroelectric material layer 145. According to an exemplary embodiment, the conducting layer 150 comprises a LNO layer that can be deposited to a thickness of about 20˜100 nm using a sputtering process on the ferroelectric material layer 145 and a platinum layer that can be deposited to a thickness of about 20˜50 nm on the LNO layer.

In view of the foregoing, it will be understood by those skilled in the art that the methods of the present invention can facilitate fabrication of a ferroelectric capacitor in an integrated circuit. The above-described embodiments have been provided by way of example, and the present invention is not limited to these examples. Multiple variations and modification to the disclosed embodiments will occur, to the extent not mutually exclusive, to those skilled in the art upon consideration of the foregoing description. Additionally, other combinations, omissions, substitutions and modifications will be apparent to the skilled artisan in view of the disclosure herein. Accordingly, the present invention is not intended to be limited by the disclosed embodiments, but is to be defined by reference to the appended claims.

What is claimed is:

1. A method for fabricating a ferroelectric capacitor in an integrated circuit, the method comprising:
fabricating a metal-oxide-semiconductor transistor on a substrate;
depositing an insulating layer on the metal-oxide-semiconductor transistor;
depositing a conducting layer on the insulating layer using a low temperature process; and
depositing a ferroelectric layer on the conducting layer using a low temperature process.

2. The method as set forth in claim 1, wherein the depositing of an insulating layer comprises depositing a silicon dioxide layer.

3. The method as set forth in claim 1, wherein the depositing of a conducting layer on the insulating layer comprises:
depositing a first conducting layer on the insulating layer; and
depositing a second conducting layer on the first conducting layer.

4. The method as set forth in claim 3, wherein the depositing of a first conducting layer comprises depositing a platinum layer.

5. The method as set forth in claim 3, wherein the depositing of a first conducting layer comprises depositing an iridium layer.

6. The method as set forth in claim 3, wherein the depositing of a second conducting layer comprises depositing a layer of conducting oxide.

7. The method as set forth in claim 6, wherein the depositing of a layer of conducting oxide comprises depositing a layer of lanthanum nickel oxide (LaNiO₃).

8. The method as set forth in claim 6, wherein the depositing of a layer of conducting oxide comprises depositing a layer of iridium oxide (IrO₂).

9. The method as set forth in claim 7, wherein the depositing of a layer of lanthanum nitric oxide comprises depositing lanthanum nickel oxide by sputtering at a temperature of about 350° C.

10. The method as set forth in claim 7, wherein the depositing of a layer of lanthanum nickel oxide comprises causing the lanthanum nickel oxide to form a perovskite phase.

11. The method as set forth in claim 1, wherein the depositing of a ferroelectric layer comprises depositing a lead zirconate titanate layer.

12. The method as set forth in claim 11, wherein the depositing of a lead zirconate titanate layer comprises depositing a lead zirconate titanate layer using metal organic chemical vapor deposition.

13. The method as set forth in claim 11, wherein the depositing of a lead zirconate titanate layer comprises depositing a lead zirconate titanate layer using a process that operates at a temperature substantially in a range of about 450° C. to about 550° C.

14. A semiconductor element formed using the method of claim 1.

15. A semiconductor element formed using the method of claim 3.

16. A manufacturing method for fabricating a ferroelectric capacitor in an integrated circuit, the method comprising:
fabricating a metal-oxide-semiconductor transistor on a substrate;
depositing an insulating layer on the metal-oxide-semiconductor;
depositing a conducting layer on the insulating layer using a process to cause at least part of the conducting layer to form a perovskite phase; and
depositing a ferroelectric layer on the conducting layer using a process to cause at least part of the ferroelectric layer to form a perovskite phase.

17. The manufacturing method as set forth in claim 16, wherein the depositing of a conducting layer on the insulating layer comprises:
depositing a first conducting layer on the insulating layer; and
depositing a second conducting layer on the first conducting layer.

18. The manufacturing method as set forth in claim 16, wherein the depositing of a conducting layer on the insulating layer is performed using a low temperature process.

19. The manufacturing method as set forth in claim 18, wherein the depositing of a ferroelectric layer on the conducting layer is performed using a low temperature process.

20. A semiconductor element formed using a manufacturing method as set forth in claim 16.

21. A semiconductor element formed using a manufacturing method as set forth in claim 18.

22. The manufacturing method as set forth in claim 16, wherein the depositing of a ferroelectric layer comprises depositing a lead zirconate titanate layer.

23. A semiconductor element formed using a manufacturing method as set forth in claim 22.

24. A semiconductor element produced by the manufacturing method as set forth in claim 22, wherein the depositing of a lead zirconate titanate layer comprises depositing a lead zirconate titanate layer using metal organic chemical vapor deposition.

25. A semiconductor element produced by the manufacturing method as set forth in claim 22, wherein the depositing of a lead zirconate titanate layer comprises depositing a lead zirconate titanate layer using a process that operates at a temperature substantially in a range of about 450° C. to about 550° C.
